(19) United States
(12) Patent Application Publication
(10) Pub. No.: US 2018/0294364 A1
(43) Pub. Date: Oct. 11, 2018

(54) SCHOTTKY DIODE AND INTEGRATED CIRCUIT INCLUDING THE SAME

(71) Applicant: Samsung Electronics Co., Ltd., Suwon-si (KR)

(72) Inventors: Seo-In Pak, Yongin-si (KR); Yong-Don Kim, Suwon-si (KR); Seon-Joo Woo, Hwaseong-si (KR); Dae-Hyun Jo, Anyang-si (KR)

(21) Appl. No.: 15/854,259

(22) Filed: Dec. 26, 2017

(30) Foreign Application Priority Data
Apr. 11, 2017 (KR) 10-2017-0046667

(51) Int. Cl. H01L 29/872; H01L 29/06; H01L 27/08; H01L 29/66

(52) U.S. Cl. CPC H01L 29/872; H01L 29/0649; H02M 7/06; H01L 27/0814; H01L 29/66143; H01L 29/0692

(57) ABSTRACT

A schottky diode includes a conduction layer of a first conduction type, a well region of a second conduction type disposed in the conduction layer, a first isolation region disposed in the conduction layer, where the first isolation region is spaced apart from the well region, a first junction region of the second conduction type disposed in the conduction layer, where the first junction region is adjacent the first isolation region and spaced apart from the well region, a second junction region of the first conduction type disposed in the conduction layer, where the second junction region is adjacent the first isolation region and a schottky electrode covering a schottky junction surface corresponding to an upper surface of the conduction layer between the well region and the first junction region.

### CROSS-REFERENCE TO RELATED APPLICATION

This U.S. Non-provisional application claims priority under 35 USC § 119 to Korean Patent Application No. 10-2017-0046667, filed on Apr. 11, 2017, in the Korean Intellectual Property Office (KIPO), the disclosure of which is incorporated by reference in its entirety herein.

### BACKGROUND

### 1. Technical Field

Exemplary embodiments of the inventive concept relate generally to semiconductor devices, and more particularly to a schottky diode and integrated circuit including the schottky diode.

### 2. Discussion of Related Art

A schottky diode is a semiconductor device including a schottky junction located between a semiconductor and a metal. The schottky diode may exhibit a fast switching characteristic since it predominantly emits minority carriers and has little storage of minority carriers that limit switching speed. A voltage drop characteristic of a schottky diode in an on-state may be lower than that of a P-N diode. Thus, schottky diodes may be widely used in fields of communications and portable apparatuses. Performance may be enhanced by designing the schottky diode to have an increased forward current. However, increasing the forward current also increases a reverse current or a leakage current of the schottky diode.

### SUMMARY

At least one exemplary embodiment of the inventive concept provides a schottky diode with enhanced forward characteristics without degraded reverse characteristics.

At least one exemplary embodiment of the inventive concept provides an integrated circuit including a schottky diode with enhanced forward characteristics without degraded reverse characteristics.

According to an exemplary embodiment of the inventive concept, a schottky diode includes a conduction layer of a first conduction type, a first well region of a second conduction type disposed in the conduction layer, a first isolation region disposed in the conduction layer, the first isolation region spaced apart from the first well region, a first junction region of the second conduction type disposed in the conduction layer, the first junction region adjacent the first isolation region and spaced apart from the first well region, a second junction region of the first conduction type disposed in the conduction layer, the second junction region adjacent the first isolation region and a schottky electrode covering a schottky junction surface corresponding to an upper surface of the conduction layer between the first well region and the first junction region.

According to exemplary embodiment of the inventive concept, a schottky diode includes a conduction layer of an N-type, a well region of a P-type disposed in the conduction layer, a first junction region of the P-type having a ring shape in the conduction layer and surrounding the well region, the ring shaped first junction region spaced apart from the well region, an isolation region having a ring shape in the conduction layer and surrounding the ring-shaped first junction region, the ring-shaped isolation region adjacent the ring-shaped first junction region, a second junction region of the N-type having a ring shape in the conduction layer and surrounding the isolation region, the ring-shaped second junction region adjacent the ring-shaped isolation region and a schottky electrode covering a schottky junction surface corresponding to an upper surface of the conduction layer between the first well region and the ring-shaped first junction region.

According to exemplary embodiment of the inventive concept, an integrated circuit includes a plurality of schottky diodes arranged in a two-dimensional plane, each of the schottky diodes includes a conduction layer of a first conduction type, a well region of a second conduction type disposed in the conduction layer, an isolation region disposed in the conduction layer, the isolation region spaced apart from the well region, a first junction region of the second conduction type disposed in the conduction layer, the first junction region adjacent the isolation region and spaced apart from the well region, a second junction region of the first conduction type formed in the conduction layer, the second junction region adjacent to the isolation region, a schottky electrode covering a schottky junction surface corresponding to an upper surface of the conduction layer between the first well region and the first junction region and a ohmic electrode covering an ohmic junction surface corresponding to an upper surface of the second junction region.

According to exemplary embodiment of the inventive concept, a schottky diode includes a conduction layer of a first conduction type, a well region of a second conduction type disposed in the conduction layer, a first isolation region disposed in the conduction layer, where the first isolation region is spaced apart from the well region, a first junction region of the second conduction type disposed in the conduction layer adjacent a first side of the first isolation region, a second junction region of the first conduction type disposed in the conduction layer, adjacent a second side of the first isolation region opposite the first side, a schottky electrode disposed on a part of the first junction region and disposed on an entire upper surface of the well region to form an anode of the schottky diode, an ohmic electrode disposed on the second junction region to form a cathode of the schottky diode.

A schottky diode according to at least one embodiment of the inventive concept may have enhanced forward characteristics due to shortened current paths in vertical and horizontal directions to reduce a resistance and increase a forward current per unit area.

A schottky diode according to at least one embodiment of the inventive concept may have enhanced forward characteristics without degraded reverse characteristics by adopting a structure for enlarging depletion regions when a reverse bias voltage is applied.

A schottky diode according to at least one embodiment of the inventive concept may have a reduced distribution of a forward current since it does not include a well region at one side of the schottky junction, which may reduce parameters affecting DC characteristics of the schottky diode.

### BRIEF DESCRIPTION OF THE DRAWINGS

Example embodiments of the present inventive concept will be more clearly understood from the following detailed description taken in conjunction with the accompanying drawings.

FIG. 1 is a cross-sectional view of a schottky diode according to an exemplary embodiment of the inventive concept.

FIGS. 2 and 3 are diagrams illustrating exemplary embodiments of the schottky diodes depending on conduction types.

FIG. 4 is a plan view of a schottky diode according to exemplary embodiment of the inventive concept.

FIG. 5 is a cross-sectional view taken along a line A-A′ in FIG. 4.

FIG. 6 is a diagram illustrating a current path of a schottky diode according to exemplary embodiment of the inventive concept.

FIG. 7 is a diagram illustrating a current path of a schottky diode that is to be compared with the schottky diode of FIG. 6.

FIG. 8 is a diagram illustrating forward characteristics of a schottky diode according to an exemplary embodiment of the inventive concept.

FIG. 9 is a diagram illustrating reverse characteristics of a schottky diode according to an exemplary embodiment of the inventive concept.

FIG. 10 is a diagram illustrating distribution characteristics of a schottky diode according to an exemplary embodiment of the inventive concept.

FIG. 11 is a plan view of a schottky diode according to an exemplary embodiment of the inventive concept.

FIG. 12 is a cross-sectional view taken along a line B-B′ in FIG. 11.

FIG. 13 is a plan view of a schottky diode according to an exemplary embodiment of the inventive concept.

FIG. 14 is a cross-sectional view taken along a line C-C′ in FIG. 13.

FIGS. 15 and 16 are diagrams illustrating an integrated circuit according to an exemplary embodiment of the inventive concept.

FIG. 17 is a plan view of a schottky diode according to an exemplary embodiment of the inventive concept.

FIG. 18 is a cross-sectional view taken along a line D-D′ in FIG. 17.

FIGS. 19, 20 and 21 are diagrams illustrating an integrated circuit according to an exemplary embodiment of the inventive concept.

FIG. 22 is a diagram illustrating an integrated circuit according to an exemplary embodiment of the inventive concept.

FIGS. 23 and 24 are cross-sectional views of exemplary embodiments of a schottky diode included in the integrated circuit of FIG. 22.

FIG. 25 is a block diagram illustrating a semiconductor system according to an exemplary embodiment of the inventive concept.

FIG. 26 is a circuit diagram illustrating an example of a rectifier included in the semiconductor system of FIG. 25

FIGS. 27, 28, 29 and 30 are diagram illustrating manufacturing processes of a schottky diode according to exemplary embodiments of the inventive concept.

FIG. 31 is a diagram illustrating a mobile device according to an exemplary embodiment of the inventive concept.

### DETAILED DESCRIPTION OF THE EXEMPLARY EMBODIMENTS

The invention will be described more fully hereinafter with reference to the accompanying drawings, in which exemplary embodiments thereof are shown. In the drawings, like numerals refer to like elements throughout.

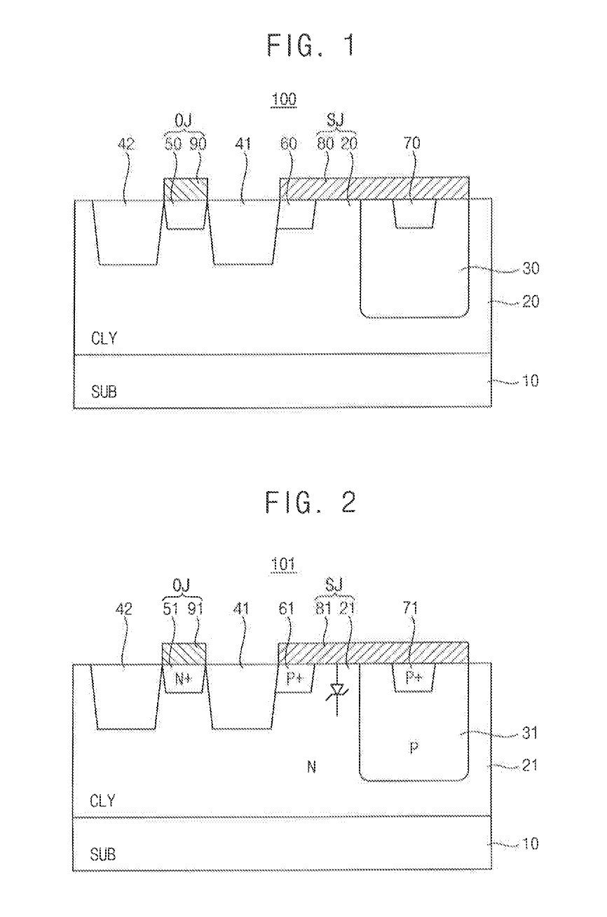

FIG. 1 is a cross-sectional view of a schottky diode according to an exemplary embodiment of the inventive concept.

Referring to FIG. 1, a schottky diode 100 includes a conduction layer CLY 20 formed on a semiconductor substrate SUB 10, a well region 30, isolation regions 41 and 42, junction regions 50, 60 and 70 formed in the conduction layer 20, and electrodes 80 and 90. In an embodiment, the isolation regions 41 and 42 are not conductive and function as insulators.

In an embodiment, the first isolation region 41 is spaced apart from the well region 30. In an embodiment, the second isolation region 42 is adjacent the second junction region 50 in a direction opposite to the first isolation region 41. In an exemplary embodiment, the second isolation region 42 is omitted. In an embodiment, the first and second isolation regions 41 and 42 have a same shape and/or thickness. In an embodiment, the well region 30 is thicker than the isolation regions 41 and 42.

In an embodiment, the first junction region 60 is adjacent the first isolation region 41 in a direction toward the well region 30. In an embodiment, the first junction region 60 is spaced apart from the well region 30. In an embodiment, the second junction region 50 is adjacent the first isolation region 41 in a direction opposite to the first junction region 60. The first isolation region 41 may be adjacent a first side of the second junction region 50 and the second isolation region 41 may be adjacent a second side of the second junction region 50 opposite the first side. The third junction region 70 may be formed in the well region 30. In an embodiment, the third junction region 70 has a higher impurity concentration than the well region 30. In an embodiment, the third junction region 71 has a same thickness as the first and second junction regions 60 and 50. In an exemplary embodiment, the third junction region 70 is omitted.

In an embodiment, the schottky electrode 80 is formed to cover a schottky junction surface corresponding to an upper surface of the conduction layer 20 between the well region 30 and the first junction region 60. For example, the schottky electrode 80 may cover upper surfaces of the first junction region 60, the well region 30, and the third junction region 70. In an embodiment, the ohmic electrode 90 covers an ohmic junction surface corresponding to an upper surface of the second junction region 50. Although not illustrated in FIG. 1, vertical contacts may be formed on the schottky electrode 80 and the ohmic electrode 90 to electrically connect them to upper wirings. In an exemplary embodiment of the inventive concept, the ohmic electrode 90 is omitted and the vertical contact is formed directly on the second junction region 50. For example, the vertical contact may directly contact the second junction region 50.

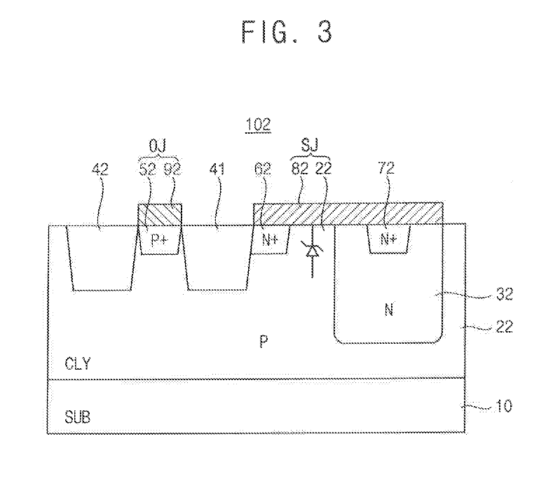

In an embodiment, the conduction layer 20 and the second junction region 50 have a first conduction type and the well region 30, the first junction region 60 and the third junction region 70 have a second conduction type that is opposite to the first conduction type. In an embodiment, one of the first and second conduction types is an N-type and the other is a P-type. It should be understood that each exemplary embodiment in this disclosure may be modified to have exchanged conduction types as illustrated in FIGS. 2 and 3.

The schottky diode 100 has a schottky junction SJ and an ohmic junction OJ. For example, a semiconductor-metal junction having a donor impurity concentration of 10¹⁷ cm-3 may correspond to the schottky junction SJ and a semiconductor-metal junction having a higher donor impurity concentration of 10¹⁹ cm-3 or more may correspond to an ohmic junction OJ.

Thus, the schottky junction SJ may be formed in a portion where the N-type conduction layer 20 having a lower impurity concentration and the schottky electrode 80 contact each other. The ohmic junction OJ may be formed in a portion where the N-type second junction region 50 having a higher impurity concentration and the ohmic electrode 90 contact each other. If the conduction layer 20 is a P-type conduction layer, the schottky junction SJ may be formed in a boundary region of the P-type conduction layer 20 having a lower impurity concentration and the schottky electrode 80 and the ohmic junction OJ may be formed at a boundary portion of the P-type second junction region 50 having a higher impurity concentration and the ohmic electrode 90.

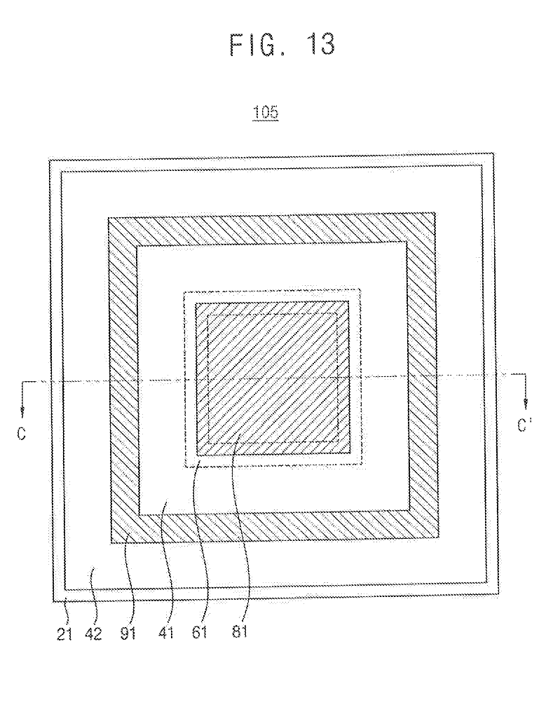

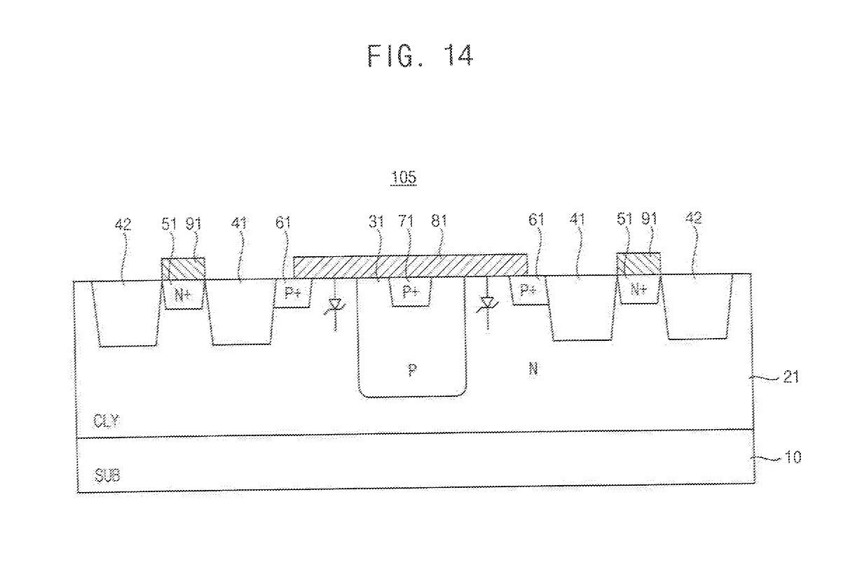

In an exemplary embodiment of the inventive concept, as illustrated in FIG. 1, the schottky electrode 80 extends to completely cover the well region 30 and the first junction region 60. In other words, the schottky electrode 80 may form the schottky junction SJ with the conduction layer 20. The ohmic junction OJ may be formed from the second junction region 50 and the ohmic electrode 90. In an exemplary embodiment of the inventive concept, as illustrated in FIGS. 13 and 14, the schottky electrode 80 extends to cover a portion of the first junction region 60 and to be spaced apart from the first isolation region 41.

In an embodiment, the schottky electrode 80 and the ohmic electrode 90 include a silicide. In an exemplary embodiment, the schottky electrode 80 and the ohmic electrode 90 include the same type of silicide. For example, the schottky electrode 80 and the ohmic electrode 90 may include a titanium (Ti) silicide, a tungsten (W) silicide, a molybdenum (Mo) silicide, a tantalum (Ta) silicide, a cobalt (Co) silicide or a nickel (Ni) silicide.

The schottky junction SJ and the ohmic junction OJ are electrically separated by the first isolation region 41 that is formed in the conduction layer 20. In an exemplary embodiment, the isolation regions 41 and 42 are implemented using a shallow trench isolation (STI). In an exemplary embodiment, the isolation regions 41 and 42 are implemented using a local oxidation of silicon (LOCOS).

The first junction region 60 is disposed to contact the schottky junction SJ so that an electric field may be dispersed and good breakdown voltage (BV) characteristics may be secured when a reverse bias is applied to the schottky diode 100. The first junction region 60 may be a well of various shapes depending on the required BV characteristics. For example, the first junction region 60 may be a pocket P-type well (PPwell) type that may be used as a source/drain of a higher voltage (HV) positive metal oxide semiconductor (PMOS) transistor or a P-type field inter-diffused multilayer process (IMP) well type that may be used as a well of a lower voltage (LV) negative metal oxide semiconductor (NMOS) transistor

The schottky diode 100 according to an exemplary embodiment of the inventive concept is located on a same semiconductor substrate in which NMOS transistors and PMOS transistors of an integrated circuit are formed.

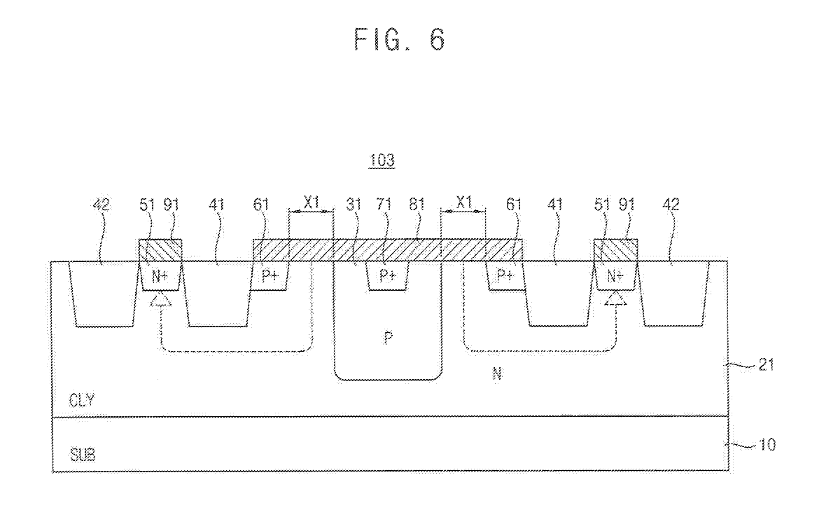

As described with reference to FIGS. 6 through 10, the schottky diode according to an exemplary embodiment may have enhanced forward characteristics due to shortened current paths in vertical and horizontal directions to reduce a resistance and increase a forward current per unit area. In addition, the schottky diode according to an exemplary embodiment of the inventive concept may have enhanced forward characteristics without degraded reverse characteristics by adopting a structure for enlarging depletion regions when a reverse bias voltage is applied. Furthermore, the schottky diode according to exemplary embodiment of the inventive concept may have reduced distribution of a forward current by removing a well region at one side of the schottky junction to reduce parameters affecting DC characteristics of the schottky diode.

FIGS. 2 and 3 are diagrams illustrating exemplary embodiments of the schottky diodes depending on different conduction types.

The fundamental structure of schottky diodes 101 and 102 of FIGS. 2 and 3 is the same as that of the schottky diode 100 of FIG. 1. Thus repeated descriptions are omitted so that differences based on the conduction types are primarily described. The disposition of an anode and a cathode of a schottky diode may be set differently by selecting the conduction types of the respective regions of the schottky diode.

Referring to FIG. 2, a schottky diode 101 includes a conduction layer CLY 21 formed on a semiconductor substrate SUB 10, a well region 31, isolation regions 41 and 42, junction regions 51, 61 and 71 formed in the conduction layer 20, and electrodes 81 and 91. In the exemplary embodiment of FIG. 2, the first conduction type corresponds to an N-type and the second conduction type corresponds to a P-type. The conduction layer 21 and the second junction region 51 correspond to the N-type. The second junction region 51 may be doped with an N-type impurity to have a higher impurity concentration than the conduction layer 21. The well region 31, the first junction region 61 and the third junction region 71 correspond to the P-type. The first and third junction regions 61 and 71 may be doped with a P-type impurity to have a higher impurity concentration than the well region 31. As a result, the schottky electrode 81 may correspond to an anode and the ohmic electrode 91 may correspond to a cathode.

Referring to FIG. 3, a schottky diode 102 includes a conduction layer CLY 22 disposed on a semiconductor substrate SUB 10, a well region 32, isolation regions 41 and 42, junction regions 52, 62 and 72 disposed in the conduction layer 22, and electrodes 82 and 92. In the exemplary embodiment of FIG. 3, the first conduction type corresponds to the P-type and the second conduction type corresponds to the N-type. The conduction layer 22 and the second junction region 52 correspond to the P-type. The second junction region 52 may be doped with a P-type impurity to have a higher impurity concentration than the conduction layer 22. The well region 32, the first junction region 62 and the third junction region 72 correspond to the N-type. The first and third junction regions 62 and 72 may be doped with an N-type impurity to have a higher impurity concentration than the well region 32. As a result, the schottky electrode 82 may correspond to a cathode and the ohmic electrode 92 may correspond to an anode.

Hereinafter, exemplary embodiments are described mainly for cases where the first conduction type is the N-type and the second conduction type is the P-type. It should be understood that each exemplary embodiment in this disclosure may be modified to cases where the first conduction type is the P-type and the second conduction type is the N-type.

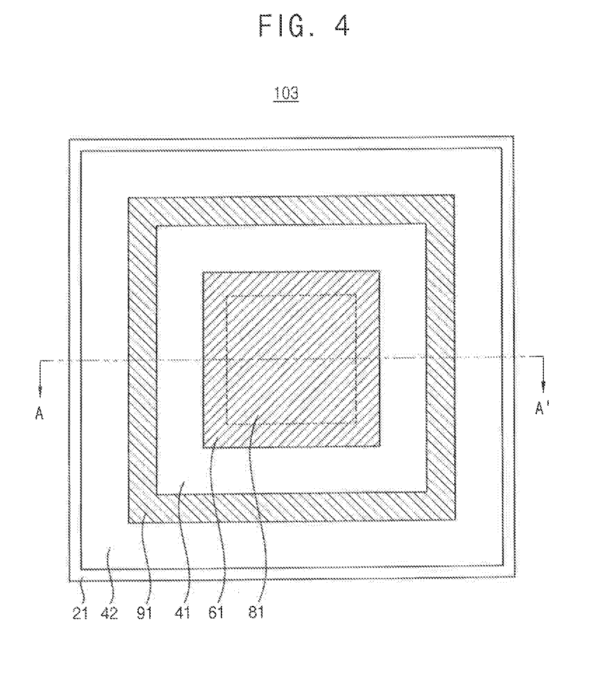

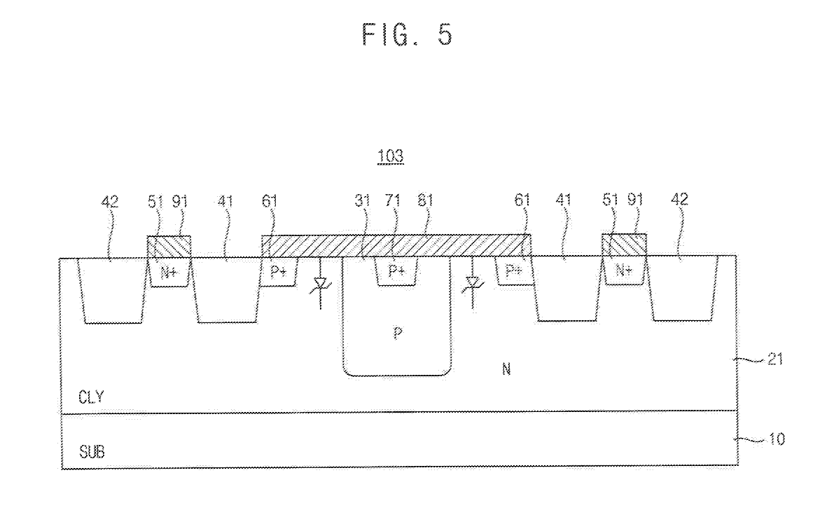

FIG. 4 is a plan view of a schottky diode according to an exemplary embodiment of the inventive concept, and FIG. 5 is a cross-sectional view taken along a line A-A′ in FIG. 4.

The fundamental structure of a schottky diode 103 of FIGS. 4 and 5 is the same as that of the schottky diode 100 of FIG. 1. Thus the repeated descriptions are omitted so that a ring shaped embodiment can be described.

Referring to FIGS. 4 and 5, a schottky diode 103 includes a conduction layer CLY 21 disposed on a semiconductor substrate SUB 10, a well region 31, isolation regions 41 and 42, junction regions 51, 61 and 71 disposed in the conduction layer 21, and electrodes 81 and 91. In the exemplary embodiment of FIG. 2, the first conduction type corresponds to an N-type and the second conduction type corresponds to a P-type. The conduction layer 21 and the second junction region 51 correspond to the N-type. The second junction region 51 may be doped with an N-type impurity to have a higher impurity concentration than the conduction layer 21. The well region 31, the first junction region 61 and the third junction region 71 correspond to the P-type. The first and third junction regions 61 and 71 may be doped with a P-type impurity to have a higher impurity concentration than the well region 31. As a result, the schottky electrode 81 may correspond to an anode and the ohmic electrode 91 may correspond to a cathode.

In an embodiment, the first isolation region 41 is spaced apart from the well region 31. The second isolation region 42 may be adjacent to the second junction region 51 in a direction opposite to the first isolation region 41. In an exemplary embodiment, the second isolation region 42 is omitted.

The first junction region 61 may be adjacent the first isolation region 41 in a direction toward the well region 31 and the first junction region 61 may be spaced apart from the well region 31. The second junction region 51 may be adjacent the first isolation region 41 in a direction opposite to the first junction region 61. In an embodiment, the third junction region 71 is disposed in the well region 31. The third junction region 71 may have a higher impurity concentration than the well region 31. In an exemplary embodiment, the third junction region 71 is omitted.

The schottky electrode 81 may be formed to cover a schottky junction surface corresponding to an upper surface of the conduction layer 21 between the well region 31 and the first junction region 61. The ohmic electrode 91 may be formed to cover an ohmic junction surface corresponding to an upper surface of the second junction region 51. Although not illustrated in FIG. 5, vertical contacts may be formed on the schottky electrode 81 and the ohmic electrode 91 to electrically connect them to upper wirings. In an exemplary embodiment, the ohmic electrode 91 is omitted and the vertical contact directly contacts the second junction region 51.

In the schottky diode 103, the well region 31 is formed at a center portion of the schottky diode 103 and the first junction region 61, the first isolation region 41 and the second isolation region 42 are formed sequentially in a shape of rings to surround the well region 31. For example, the ring of the second isolation region 42 passes through the left most portion of the second isolation region 42 and the right most portion of the second isolation region 42 shown in FIG. 5. For example, the ring of the first isolation region 41 passes through the left most portion of the first isolation region 41 and the right most portion of the first isolation region 41 shown in FIG. 5. In an exemplary embodiment, the schottky diode 103 includes the second isolation region 42 formed in a shape of a ring in the conduction layer 21 to surround the ring-shaped second junction region 51 such that the ring-shaped second isolation region 42 is adjacent the ring-shaped second junction region 51.

In an exemplary embodiment, the schottky junction surface corresponding to the upper surface of the conduction layer 21 between the well region 31 and the first junction region 61 is formed in a shape of a ring between the well region 31 and the ring-shaped first junction region 61. In this case, the schottky electrode 81 may be formed in a shape of a convex polygon to cover the well region 31, the ring-shaped schottky junction surface and the ring-shaped first junction region 61. While FIG. 4 illustrates the schottky electrode 81 as a quadrangle, the inventive concept is not limited thereto. For example, the schottky diode 81 may have various shapes such as a circle, a pentagon, a hexagon, etc.

As a result, the ring-shaped first junction region 61 may be disposed under an outer rim portion of the schottky electrode 81 of the polygon shape.

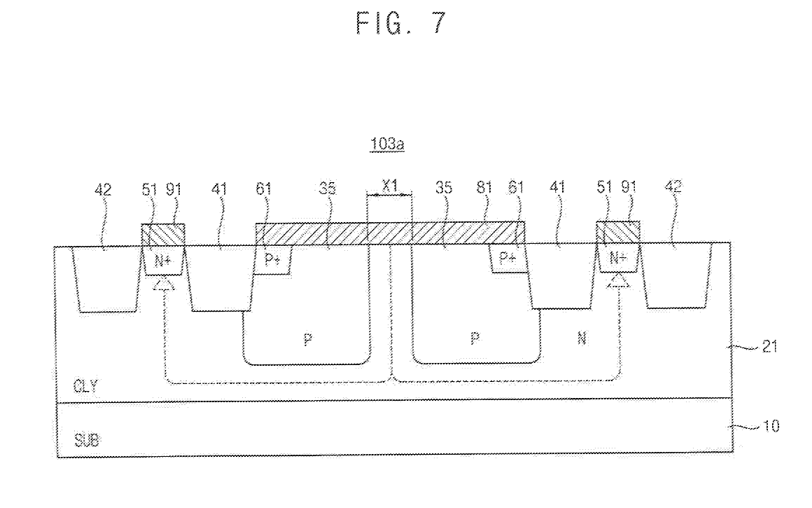

FIG. 6 is a diagram illustrating a current path of a schottky diode according to an exemplary embodiment of the inventive concept, and FIG. 7 is a diagram illustrating a current path of a schottky diode that is being compared with the schottky diode of FIG. 6.

The structure of a schottky diode 103 of FIG. 6 is the same as that of FIGS. 4 and 5, and thus repeated descriptions are omitted. The schottky diode 103a of FIG. 7 is similar to that of FIG. 6.

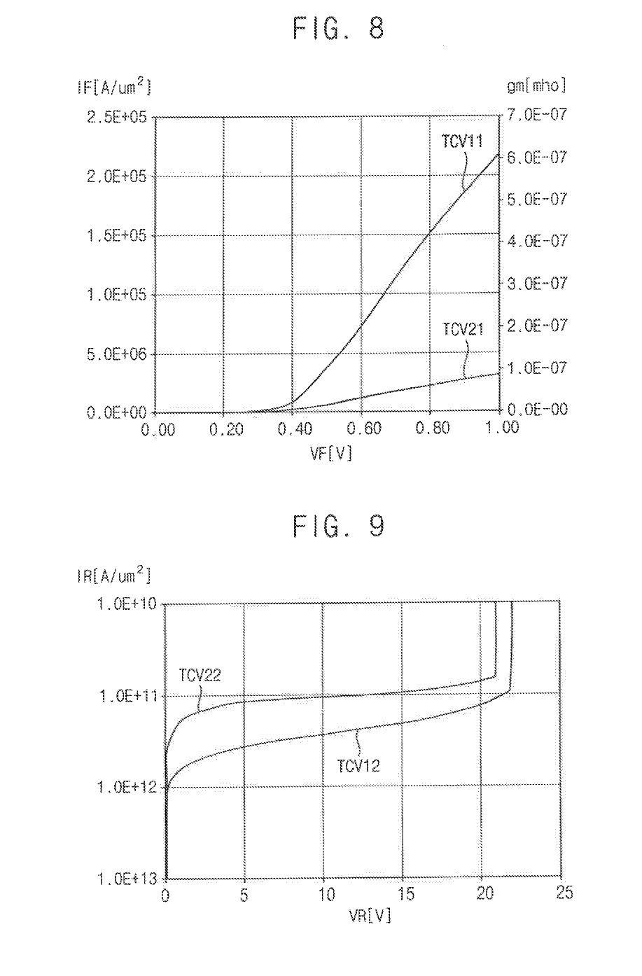

A current path is formed between the first P-type well region 31 at the center portion and the ring-shaped first junction region 61 in the schottky diode 103 of FIG. 6 whereas a current path is formed at a center portion of the P-type well region 35 in the schottky diode 103a of FIG. 7. In FIGS. 7 and 8, X1 indicates a width of a forward current path.

In the schottky diode 103a of FIG. 7, the P-type well regions 35 are disposed at both sides of an anode. In the schottky diode 103 of FIG. 6, the P-type well region 35 of FIG. 7 is replaced with the P-type well region 31 at the center portion of the anode. Thus the vertical-direction resistance or the junction-field effect transistor (J-FET) resistance of a current path from the schottky junction to the lower portion and the horizontal resistance or the drift resistance of a current path under the isolation region may be reduced in the schottky diode 103 of FIG. 6 in comparison with the schottky diode 103a of FIG. 7. The schottky diode has an asymmetric structure between the P-type well region 31 and the first junction region 61 to reduce the current path and thus the vertical and the horizontal resistances may be reduced.

FIG. 8 is a diagram illustrating forward characteristics of a schottky diode according to an exemplary embodiment of the inventive concept.

In FIG. 8, the horizontal axis represents a forward bias voltage (VF) and the vertical axis represents a forward current IF per unit area. A first trend curve TCV11 corresponds to the schottky diode 103 of FIG. 6 according to an exemplary embodiment and a second trend curve TCV12 corresponds to the schottky diode 103a of FIG. 7. As illustrated in FIG. 8, the schottky diode 103 of FIG. 6 has an increased forward current IF in comparison with the schottky diode 103a of FIG. 7.

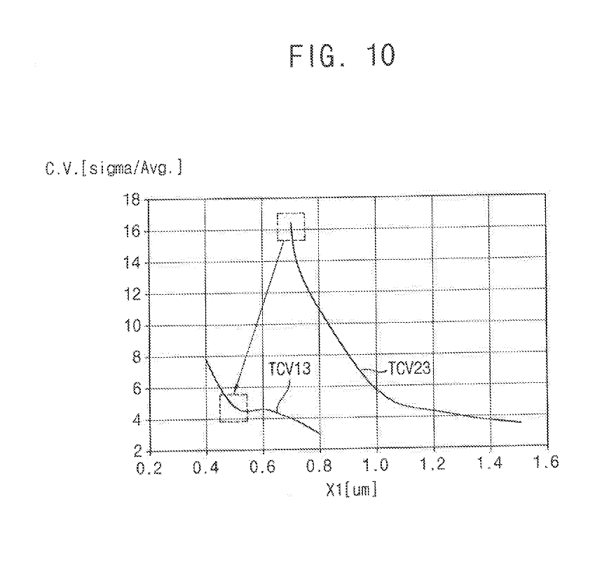

FIG. 9 is a diagram illustrating reverse characteristics of a schottky diode according to an exemplary embodiment of the inventive concept.

In FIG. 9, the horizontal axis represents a reverse bias voltage VR and the vertical axis represents a reverse current IR per unit area. A first trend curve TCV12 corresponds to the schottky diode 103 of FIG. 6 according to an exemplary embodiment and a second trend curve TCV22 corresponds to the schottky diode 103a of FIG. 7. As illustrated in FIG. 9, the schottky diode 103 of FIG. 6 has a reduced reverse current IR in comparison with the schottky diode 103a of FIG. 7. In addition, the schottky diode 103 of FIG. 6 has an increased breakdown voltage corresponding to an abrupt increase of the reverse current IR and thus enhanced reverse characteristics in comparison with the schottky diode 103a of FIG. 7.

FIG. 10 is a diagram illustrating distribution characteristics of a schottky diode according to an exemplary embodiment of the inventive concept.

In FIG. 10, the horizontal axis represents a width of a current path illustrated in FIGS. 6 and 7 and the vertical axis represents a coefficient variance (C. V.) of the forward current. A coefficient variance may be referred to as a standard deviation coefficient that is determined as a value of m/σ where m is an average of a variable and σ is a deviation of the variable.

A first trend curve TCV13 corresponds to the schottky diode 103 of FIG. 6 according to an exemplary embodiment and a second trend curve TCV23 corresponds to the schottky diode 103a of FIG. 7. In general, the coefficient variance decreases as the width X1 increases because the forward current IF increases as the width X2 increases. However, the reverse current IR or the leakage current increases as the width X1 increases, and thus a smaller coefficient variance is desirable. As illustrated in FIG. 10, the coefficient variance of the forward current of the schottky diode 103 is about a quarter of that of the schottky diode 103a of FIG. 7.

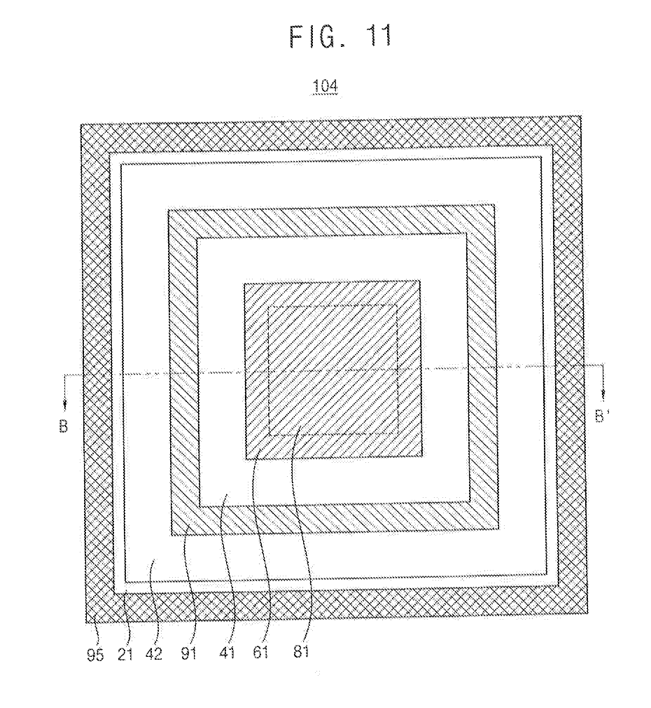

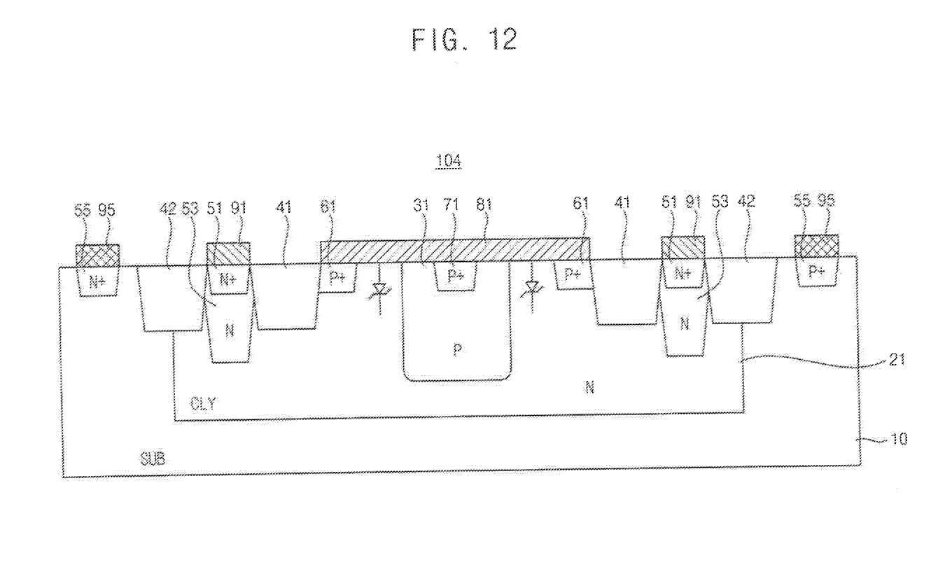

FIG. 11 is a plan view of a schottky diode according to an exemplary embodiment of the inventive concept, and FIG. 12 is a cross-sectional view taken along a line B-B′ in FIG. 11.

The fundamental structure of a schottky diode 104 of FIGS. 11 and 12 is the same as that of the schottky diode 103 of FIGS. 4 and 5, and thus repeated descriptions are omitted.

Referring to FIGS. 11 and 12, a schottky diode 104 includes a conduction layer CLY 21 disposed in a semiconductor substrate SUB 10, well regions 31 and 53, isolation regions 41 and 42, junction regions 51, 61, 71 and 55 disposed in the conduction layer 21, and electrodes 81, 91 and 95. The conduction layer 21 and the second junction region 51 correspond to the N-type. The second junction region 51 may be doped with an N-type impurity to have a higher impurity concentration than the conduction layer 21. The first well region 31, the first junction region 61 and the third junction region 71 correspond to the P-type. The first and third junction regions 61 and 71 may be doped with a P-type impurity to have a higher impurity concentration than the well region 31. As a result, the schottky electrode 81 may correspond to an anode and the ohmic electrode 91 may correspond to a cathode.

In the schottky diode 104, the first well region 31 is formed at a center portion of the schottky diode 103 and the first junction region 61, the first isolation region 41 and the second isolation region 42 are formed sequentially in a shape of rings to surround the first well region 31. In an embodiment, the distance between a left edge of the first well region 31 and a left edge of the schottky electrode 81 is the same as the distance between a right edge of the first well region 31 and the right edge of the schottky electrode 81. In an exemplary embodiment, the schottky diode 104 includes the second isolation region 42 formed in a shape of a ring in the conduction layer 21 to surround the ring-shaped second junction region 51 such that the ring-shaped second isolation region 42 is adjacent the ring-shaped second junction region 51.

The schottky junction surface corresponding to the upper surface of the conduction layer 21 between the first well region 31 and the first junction region 61 may be formed in a shape of a ring between the first well region 31 and the ring-shaped first junction region 61. In this case, the schottky electrode 81 may be formed in a shape of a convex polygon to cover the first well region 31, the ring-shaped schottky junction surface and the ring-shaped first junction region 61.

As illustrated in FIGS. 11 and 12, the schottky diode 104 may further include the ohmic junction that pulls the leakage current from the conduction layer 21 to the semiconductor substrate 10. The ohmic junction 55 and 95 may include a fourth junction region 55 and an electrode 95 contacting the fourth junction region 55. The fourth junction region 55 may be formed in a shape of a ring to surround the ring-shaped second isolation region 42. For example, the ring of the fourth junction region 55 may pass through the left most portion of the fourth junction region 55 and the right most portion of the fourth junction region 55 illustrated in FIG. 12. In an embodiment, the electrode 95 includes a silicide. For example, the electrode 95 may include a titanium (Ti) silicide, a tungsten (W) silicide, a molybdenum (Mo) silicide, a tantalum (Ta) silicide, a cobalt (Co) silicide or a nickel (Ni) silicide.

The ohmic junction 55 and 95 may pull the leakage current from the conduction layer 21 to reduce or prevent the leakage current from flowing into the semiconductor substrate 10, which may cause defects of the schottky diode 104. The ohmic junction 55 and 95 may be electrically separated from the other ohmic junction 51 and 91 by the second isolation region 42.

In addition, as illustrated in FIGS. 11 and 12, the schottky diode 104 further includes the second well region 53 in comparison with the schottky diode 103 of FIGS. 4 and 5. In an embodiment, the second well region 53 of the N-type is located under the second junction region 51. In an embodiment, the second well region 53 has an impurity concentration higher than the conduction layer 21 and lower than the second junction region 51. The second well region 53 may be deeper than the first isolation region 41. For example, a bottom surface of the second well region 53 is lower than a bottom surface of the first isolation layer 41. The forward current from the schottky junction 21 and 81 may be further pulled using the second well region 53.

FIG. 13 is a plan view of a schottky diode according to an exemplary embodiment of the inventive concept, and FIG. 14 is a cross-sectional view taken along a line C-C′ in FIG. 13.

The fundamental structure of a schottky diode 105 of FIGS. 13 and 14 is the same as that of the schottky diode 103 of FIGS. 4 and 5, and thus repeated descriptions are omitted.

Referring to FIGS. 13 and 14, a schottky diode 105 includes a conduction layer CLY 21 disposed on a semiconductor substrate SUB 10, well region 31, isolation regions 41 and 42, junction regions 51, 61, and 71 disposed in the conduction layer 21, and electrodes 81 and 91. The conduction layer 21 and the second junction region 51 correspond to the N-type. The second junction region 51 may be doped with an N-type impurity to have a higher impurity concentration than the conduction layer 21. The first well region 31, the first junction region 61 and the third junction region 71 correspond to the P-type. The first and third junction regions 61 and 71 may be doped with a P-type impurity to have a higher impurity concentration than the well region 31. As a result, the schottky electrode 81 may correspond to an anode and the ohmic electrode 91 may correspond to a cathode.

In the schottky diode 105, the first well region 31 is formed at a center portion of the schottky diode 103 and the first junction region 61, the first isolation region 41 and the second isolation region 42 are formed sequentially in a shape of rings to surround the first well region 31. In an exemplary embodiment, the schottky diode 104 includes the second isolation region 42 formed in a shape of a ring in the conduction layer 21 to surround the ring-shaped second junction region 51 such that the ring-shaped second isolation region 42 is adjacent the ring-shaped second junction region 51.

The schottky junction surface corresponding to the upper surface of the conduction layer 21 between the first well region 31 and the first junction region 61 may be formed in a shape of a ring between the first well region 31 and the ring-shaped first junction region 61. In this case, the schottky electrode 81 may be formed in a shape of a convex polygon to cover the first well region 31, the ring-shaped schottky junction surface and the ring-shaped first junction region 61.

As illustrated in FIGS. 13 and 14, the schottky electrode 81 of the schottky diode 105 extends to cover a portion of the first junction region and to be spaced apart from the first isolation region, in comparison with the schottky diode 103 of FIGS. 4 and 5. For example, instead of the schottky electrode entirely covering an upper surface of the first junction region 61, a part of the upper surface of the first junction region 61 is exposed.

As described above, the schottky electrode 81 and the ohmic electrode 91 may include a silicide. For example, the schottky electrode 80 and the ohmic electrode 90 may include a titanium (Ti) silicide, a tungsten (W) silicide, a molybdenum (Mo) silicide, a tantalum (Ta) silicide, a cobalt (Co) silicide or a nickel (Ni) silicide. In this case, silicide defects, which may be caused at end portions of the schottky junction, may be prevented by forming the schottky electrode 81 to be spaced apart from the first isolation region 41.

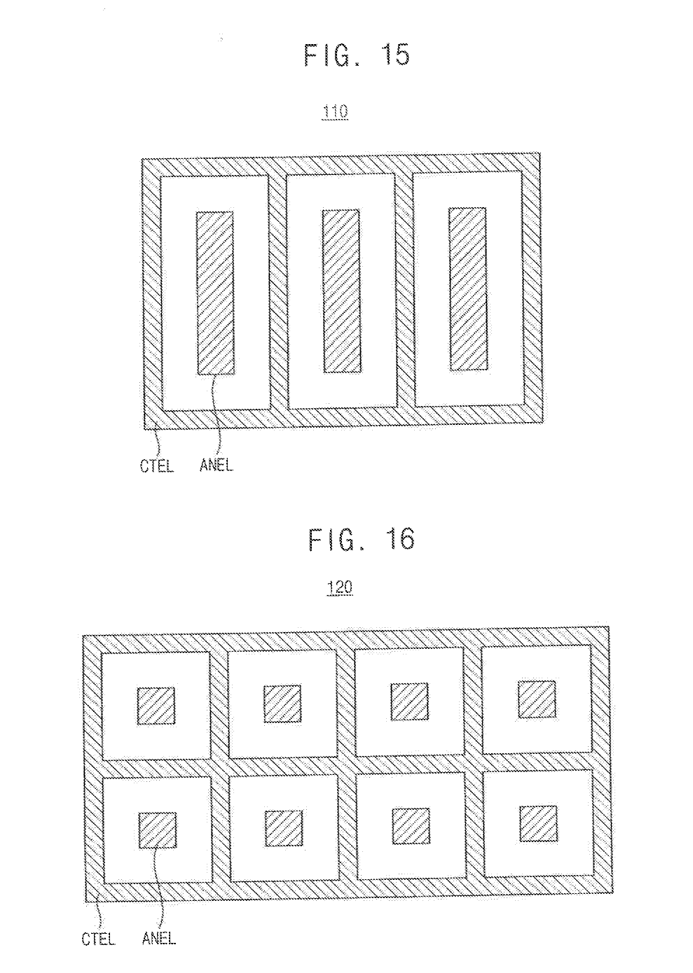

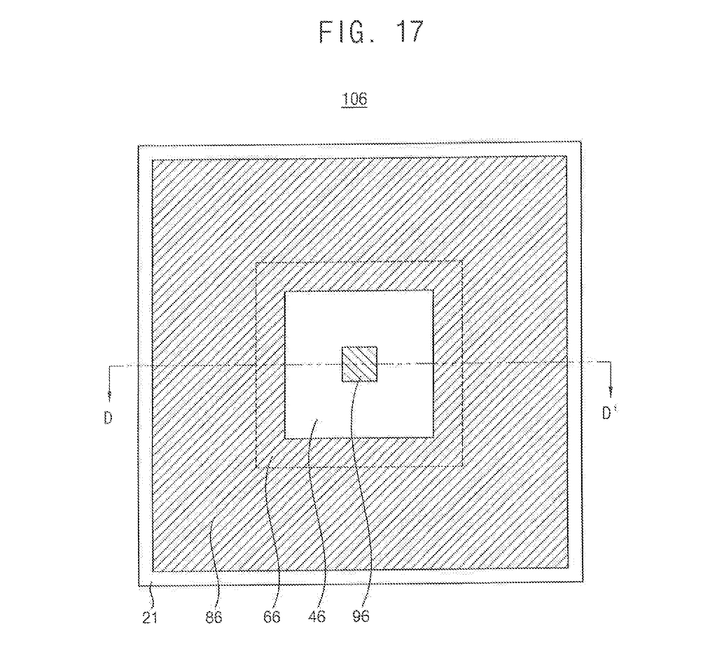

FIGS. 15 and 16 are diagrams illustrating an integrated circuit according to an exemplary embodiment of the inventive concept.

Referring to FIGS. 15 and 16, each of integrated circuits 110 and 120 may include a plurality of schottky diodes arranged in a two-dimensional plane. As described above, each of the schottky diodes may have a structure to shorten a current path and enlarge depletion regions in case of a reverse bias. Even though only a horizontal layout is illustrated in FIGS. 15 and 16, it should be understood that the vertical structures of FIGS. 1, 3, 5, 6, 7, 12 and 14 may be applied to the integrated circuits 110 and 120.

As illustrated in FIGS. 15 and 16, the schottky electrodes ANEL of the plurality of schottky diodes may be arranged in a form of a matrix of at least one row and at least one column. For example, the schottky electrodes ANEL may be arranged in a single row as illustrated in FIG. 15, or the schottky electrodes ANEL may be arranged in multiple rows as illustrated in FIG. 16. The ohmic electrodes CTEL of the plurality of the schottky diodes may be formed in a shape of a mesh to surround the schottky electrodes ANEL of a dot shape. As such, the forward current per unit area may be increased using the structure sharing the ohmic electrodes CTEL. In an embodiment, the ohmic electrodes CTEL has a shape of multiple adjacent frames arranged in one or more rows or columns.

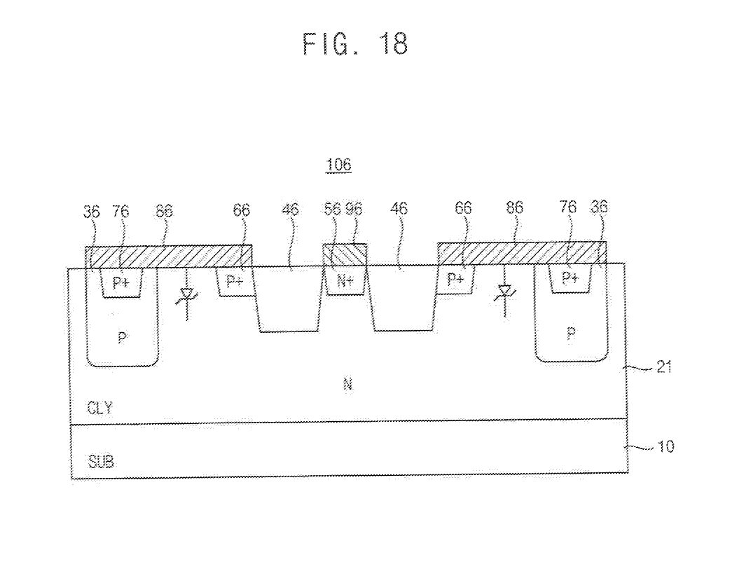

FIG. 17 is a plan view of a schottky diode according to an exemplary embodiment of the inventive concept, and FIG. 18 is a cross-sectional view taken along a line D-D′ in FIG. 17.

The fundamental structure of a schottky diode 106 of FIGS. 4 and 5 is to the same as that of the schottky diode 100 of FIG. 1. Thus repeated descriptions are omitted so that a ring shape can be primarily described.

Referring to FIGS. 17 and 18, a schottky diode 106 includes a conduction layer CLY 21 disposed on a semiconductor substrate SUB 10, a well region 36, an isolation region 46, junction regions 56, 66 and 76 disposed in the conduction layer 21, and electrodes 86 and 96. The conduction layer 21 and the second junction region 56 correspond to the N-type. The second junction region 56 may be doped with an N-type impurity to have a higher impurity concentration than the conduction layer 21. The well region 36, the first junction region 66 and the third junction region 76 correspond to the P-type. The first and third junction regions 66 and 76 may be doped with a P-type impurity to have a higher impurity concentration than the well region 36. As a result, the schottky electrode 86 may correspond to an anode and the ohmic electrode 96 may correspond to a cathode.

In an embodiment, the first isolation region 46 is spaced apart from the well region 36. In an embodiment, the first junction region 66 is adjacent the first isolation region 46 in a direction toward the well region 36. In an embodiment, the first junction region 66 is spaced apart from the well region 36. In an embodiment, the second junction region 56 is adjacent the isolation region 46 in a direction opposite to the first junction region 66. The third junction region 76 may be formed in the well region 36 and the third junction region 76. In an embodiment, the third junction region has a higher impurity concentration than the well region 36. In an exemplary embodiment, the third junction region 76 is omitted.

The schottky electrode 86 may be formed to cover a schottky junction surface corresponding to an upper surface of the conduction layer 21 between the well region 36 and the first junction region 66. The ohmic electrode 96 may be formed to cover an ohmic junction surface corresponding to an upper surface of the second junction region 56. Although not illustrated in FIGS. 17 and 18, vertical contacts may be formed on the schottky electrode 86 and the ohmic electrode 96 to electrically connect them to upper wirings. For example, the vertical contacts may directly connect the schottky electrode 86 and the ohmic electrode 96. In an exemplary embodiment, the ohmic electrode 91 is omitted and thus the vertical contact may be formed directly on the second junction region 56. For example, the vertical contact may directly contact the second junction region 56.

In the schottky diode 106, the second junction region 56 is formed at a center portion of the schottky diode 106 and the isolation region 46, the first junction region 66 and the well region 36 are formed sequentially in a shape of rings to surround the second junction region 56.

The schottky junction surface corresponding to the upper surface of the conduction layer 21 between the well region 36 and the first junction region 66 may be formed in a shape of a ring between the ring-shaped well region 36 and the ring-shaped first junction region 66. In this case, the schottky electrode 86 may be formed in a shape of a ring to cover the ring-shaped well region 36, the ring-shaped schottky junction surface and the ring-shaped first junction region 66. While FIG. 17 illustrates the schottky electrode 86 as a rectangular ring, the inventive concept is not limited thereto. For example, the schottky diode 86 may have various shapes such as a circular ring, a pentagonal ring, a hexagonal ring, etc.

As a result, the ring-shaped first junction region 66 may be disposed under an inner rim portion of the schottky electrode 86 of the ring shape.

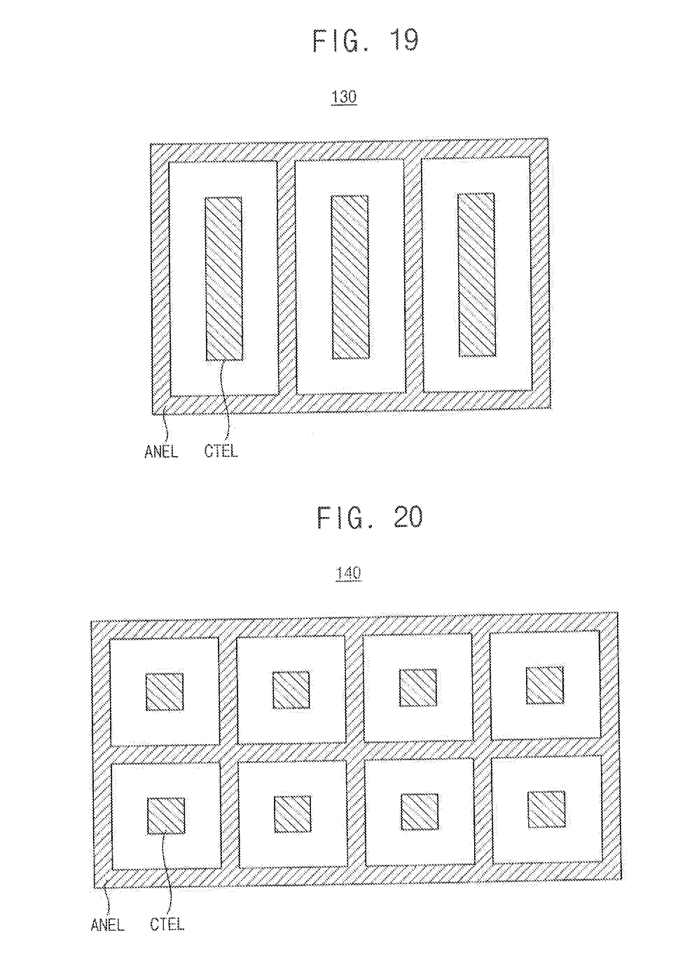

FIGS. 19, 20 and 21 are diagrams illustrating an integrated circuit according to an exemplary embodiment of the inventive concept.

Referring to FIGS. 19, 20 and 21, each of integrated circuits 130, 140 and 150 may include a plurality of schottky diodes arranged in a two-dimensional plane. As described above, each of the schottky diodes may have a structure to shorten a current path and enlarge depletion regions in case of a reverse bias. Although only a horizontal layout is illustrated in FIGS. 19, 20 and 21, it should be understood that the vertical structures of FIGS. 1, 3 and 18 may be applied to the integrated circuits 130, 140 and 150.

As illustrated in FIGS. 19 and 20, the ohmic electrodes CTEL of the plurality of schottky diodes may be arranged in a form of a matrix of at least one row and/or at least one column. For example, the ohmic electrodes CTEL may be arranged in a single row as illustrated in FIG. 19, or the ohmic electrodes CTEL may be arranged in multiple rows as illustrated in FIG. 20. The schottky electrodes ANEL of the plurality of the schottky diodes may be formed in a shape of a mesh to surround the ohmic electrodes CTEL of a dot shape. As such, the forward current per unit area may be increased using the structure sharing the schottky electrodes ANEL.

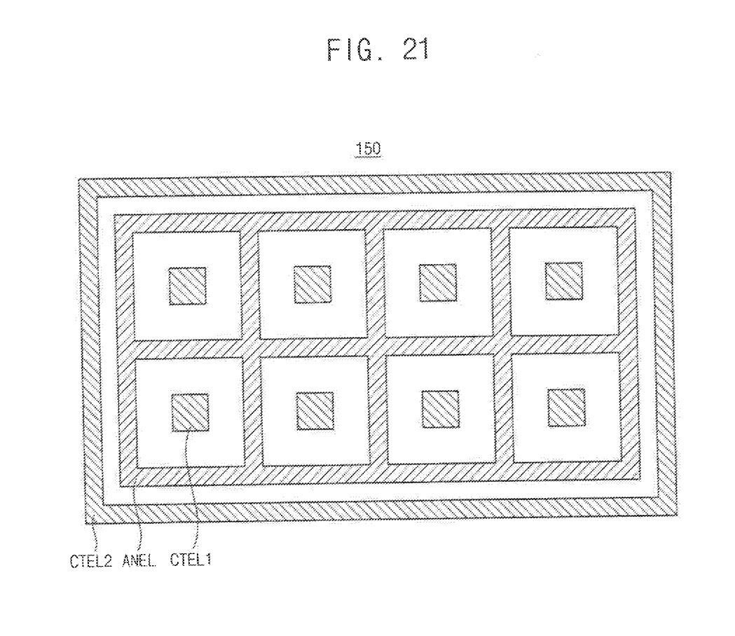

In comparison with the integrated circuit 140 of FIG. 20, the integrated circuit 150 of FIG. 21 may further include a ring-shaped ohmic electrode CTEL2 in addition to the dot-shaped ohmic electrodes CTEL1. Using the ring-shaped ohmic electrode CTEL2 at the outer rim of the diode array, the width of the current path may be increased and the schottky diode region may be defined without additional isolation regions.

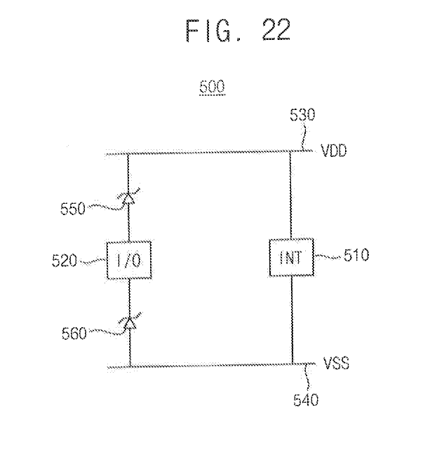

FIG. 22 is a diagram illustrating an integrated circuit according to an exemplary embodiment of the inventive concept.

FIG. 22 illustrates an example of an electrostatic discharge (ESD) protection circuit 500. Referring to FIG. 22, an ESD protection circuit 500 includes an internal circuit 510, a signal input/output terminal 520, first and second power lines 530 and 540 and first and second schottky diodes 550 and 560, which are electrically connected as such. The first and second power lines 530 and 540 may be connected to a power supply voltage VDD and a ground voltage VSS, respectively.

In an embodiment, the cathode of the first schottky diode 550 is electrically connected to the first power line 530 and the anode of the first schottky diode 550 is electrically connected to the signal input/output terminal 520. In this embodiment, the anode of the second schottky diode 560 is electrically connected to the second power line 540 and the cathode of the second schottky diode 560 is electrically connected to the signal input/output terminal 520.

For example, when a positive ESD surge is generated at the signal input/output terminal 520, electric potential of the input/output signal terminal 520 is increased. As a result of the electric potential increase, the first schottky diode 550 connected between the signal input/output terminal 520 and the first power line 530 becomes forward biased, and thus the positive ESD surge may be discharged through the first power line 530. As a result, the internal circuit 510 may be protected from the positive ESD surge.

For example, when a negative ESD surge is generated at the signal input/output terminal 520, the electric potential of the signal input/output terminal 520 is decreased. As a result of decreased electric potential, the second schottky diode 560 connected between the signal input/output terminal 520 and the second power line 540 becomes forward biased, and thus, the negative ESD surge may be discharged through the second power line 540. As a result, the internal circuit 510 may be protected from the negative ESD surge.

Hereinafter, an on-chip schottky diode pair is described, which may be applied to the ESD protection circuit 500 of FIG. 22.

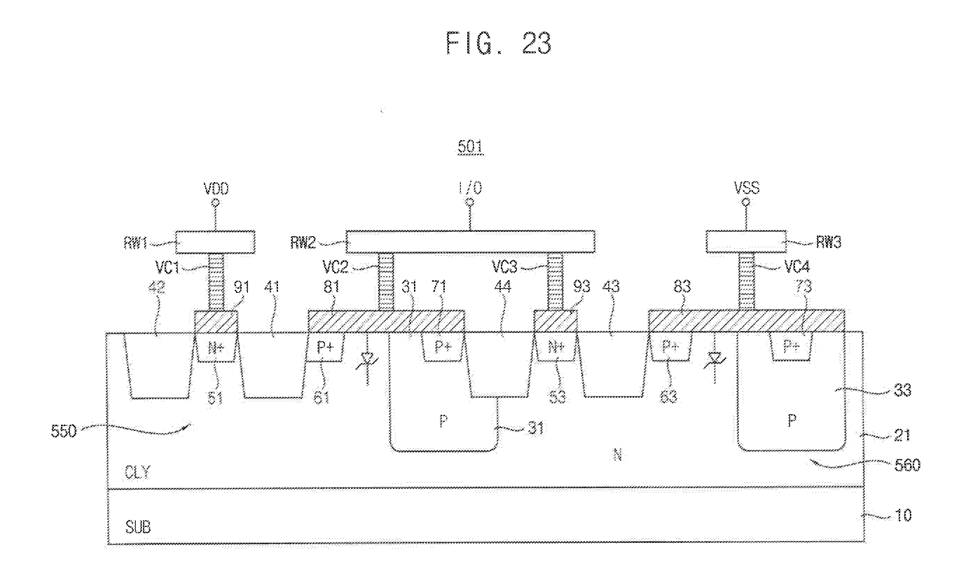

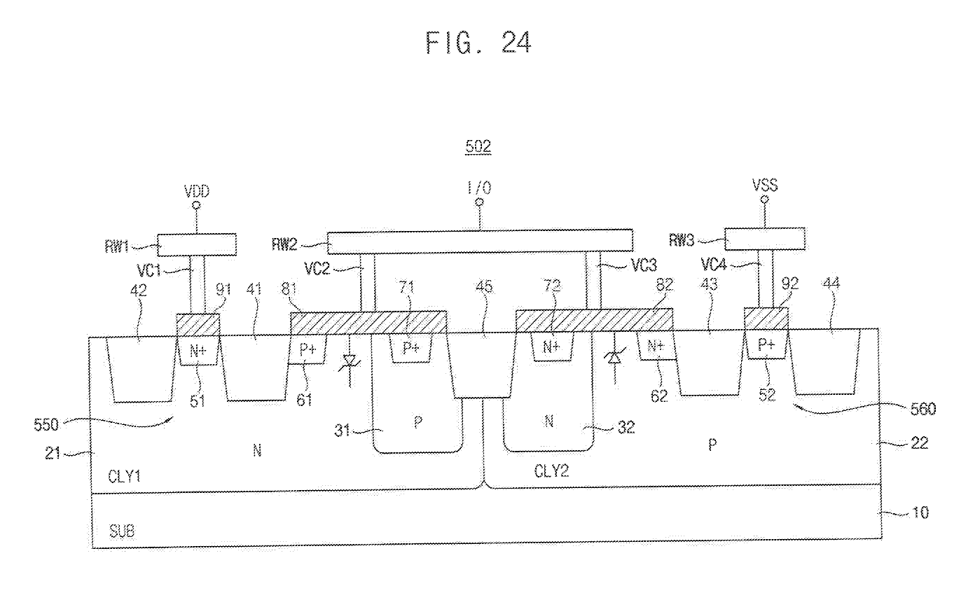

FIGS. 23 and 24 are cross-sectional views of exemplary embodiments of a schottky diode included in the integrated circuit of FIG. 22.

The fundamental structure of schottky diodes 501 and 502 of FIGS. 23 and 24 is the same as that of the schottky diodes 100, 101 and 102 of FIGS. 1, 2 and 3, and thus repeated descriptions are omitted.

Referring to FIG. 23, an integrated circuit 501 includes a conduction layer CLY 21 disposed on a semiconductor substrate SUB 10, well regions 31 and 33, isolation regions 41, 42, 43 and 44, junction regions 51, 53, 61, 63, 71 and 73 disposed in the conduction layer 21, and electrodes 81, 83, 91 and 93. The conduction layer 21 and the junction regions 51 and 53 correspond to the N-type. The junction region 51 and 53 may be doped with an N-type impurity to have a higher impurity concentration than the conduction layer 21. The well regions 31 and 33 and the junction regions 61, 63, 71 and 73 correspond to the P-type. The junction regions 61, 63, 71 and 73 may be doped with a P-type impurity to have a higher impurity concentration than the well regions 31 and 33. As a result, the schottky electrodes 81 and 83 may correspond to anodes and the ohmic electrodes 91 and 93 may correspond to cathodes.

Vertical contacts VC1, VC2, VC3 and VC4 are formed on the electrodes 81, 83, 91 and 93 to electrically connect the electrodes 81, 83, 91 and 93 to upper wirings RW1, RW2 and RW3. As illustrated in FIG. 22, a cathode of a first schottky diode 501 may be electrically connected to the power supply voltage VDD and an anode of the first schottky diode 501 may be electrically connected to the signal input/output terminal I/O. Also a cathode of a second schottky diode 502 may be electrically connected to the signal input/output terminal I/O and an anode of the second schottky diode 502 may be electrically connected to the ground voltage VSS.

Referring to FIG. 24, an integrated circuit 502 includes first and second conduction layers CLY1 21 and CLY2 22 formed on a semiconductor substrate SUB 10, first and second well regions 31 and 32, isolation regions 41, 42, 43, 44 and 45, junction regions 51, 52, 61, 62, 71 and 72 disposed in the conduction layers 21 and 23, and electrodes 81, 82, 91 and 92. The isolation regions 41 and 42 and the junction regions 51 and 61 are disposed in the conduction layer 21. The isolation regions 43 and 44 and the junction regions 52 and 62 are disposed in the conduction layer 22. The first conduction layer 21, the second well region 32 and the junction regions 51, 62 and 72 correspond to the N-type. The junction regions 51, 62 and 72 may be doped with an N-type impurity to have a higher impurity concentration than the first conduction layer 21 and the second well region 32. The second conduction layer 22, the first well region 31 and the junction regions 52, 61 and 71 correspond to the P-type. The junction regions 52, 61 and 71 may be doped with a P-type impurity to have a higher impurity concentration than the second conduction layer 22 and the first well region 31. As a result, the first schottky electrode 81 and the second ohmic electrode 92 may correspond to anodes and the second schottky electrode 82 and the first ohmic electrode 91 may correspond to cathodes.

Vertical contacts VC1, VC2, VC3 and VC4 may be formed on the electrodes 81, 82, 91 and 92 to electrically connect the electrodes 81, 82, 91 and 92 to upper wirings RW1, RW2 and RW3. As illustrated in FIG. 22, a cathode of a first schottky diode 501 may be electrically connected to the power supply voltage VDD and an anode of the first schottky diode 501 may be electrically connected to the signal input/output terminal I/O. Also a cathode of a second schottky diode 502 may be electrically connected to the signal input/output terminal I/O and an anode of the second schottky diode 502 may be electrically connected to the ground voltage VSS.

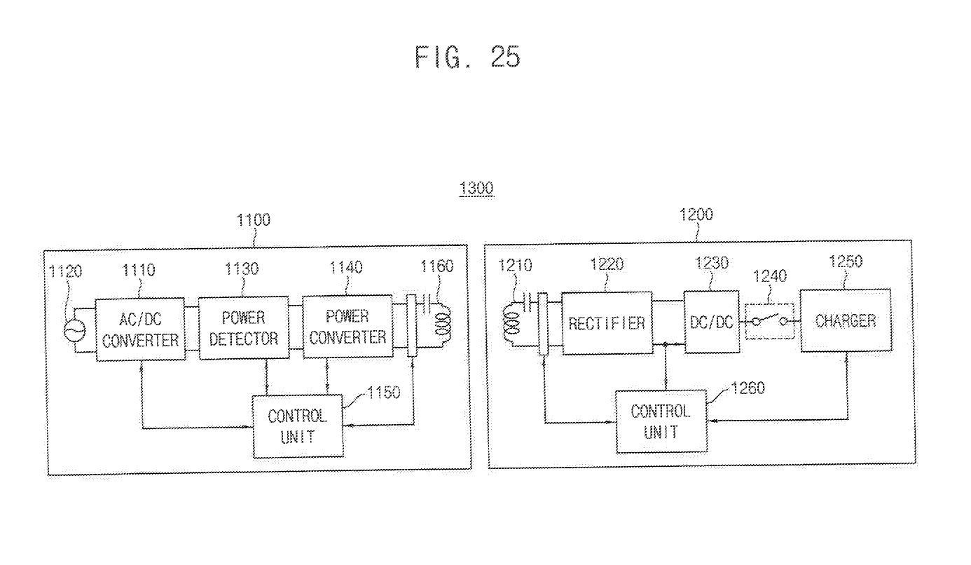

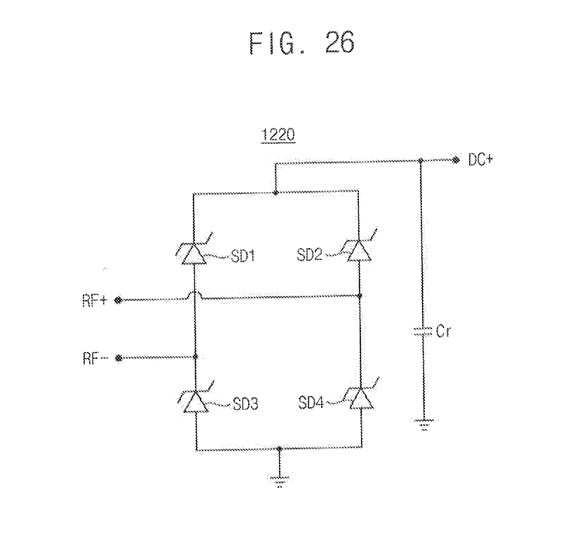

FIG. 25 is a block diagram illustrating a semiconductor system according to an exemplary embodiment of the inventive concept, and FIG. 26 is a circuit diagram illustrating an example of a rectifier included in the semiconductor system of FIG. 25

The following description will be given in conjunction with a wireless power transmission system as an example of a semiconductor system according to an exemplary embodiment of the inventive concept, but the present inventive concept is not limited thereto.

Referring to FIG. 25, a semiconductor system 1300 includes a source device 1100 and a target device 1200.

The source device 1100 includes an AC/DC converter 1110, a power detector 1130, a power converter 1140, a control unit 1150 and a source resonator 1160.

The target device 1200 includes a target resonator 1210, a rectifier 1220, a DC/DC converter 1230, a switch unit 1240, a charger 1250 and a control unit 1260.

The AC/DC converter 1110 may produce a DC voltage by rectifying an AC voltage having a bandwidth of several tens of Hz, which is output from a power supply 1120. The AC/DC converter 1110 may output a certain level of DC voltage, or adjust an output level of the DC voltage under control of the control unit 1150.

The power detector 1130 may detect a current and voltage output from the AC/DC converter 1110, and transmit information about the detected current and voltage to the control unit 1150. Further, the power detector 1130 may detect a current and voltage input to the power converter 1140.

The power converter 1140 may convert a DC voltage into an AC voltage in response to a switching pulse signal having a bandwidth ranging from several MHz to several tens of MHz to generate power. That is, the power converter 1140 may convert a DC voltage into an AC voltage using a resonant frequency to generate “communication power” or “charging power” that is used in the target device 1200.

In this case, “communication power” may refer to energy for activating a communication module and a processor of the target device 1200. As a meaning of energy for activating, “communication power” may also be referred to as wake-up power.

The communication power may be transmitted for a predetermined period of time in the form of constant waves (CW). The “charging power” may refer to energy for charging a battery connected to the target device 120 or included in the target device 1200. The charging power may be transmitted continuously for a predetermined period of time, and may be transmitted at a power level higher than that of the “communication power.” For example, the power level of the communication power may range between 0.1 Watt to 1 Watt, and the power level of the charging power may range between 1 Watt to 20 Watt.

The control unit 1150 may control a frequency of a switching pulse signal. The frequency of the switching pulse signal may be determined by the control unit 1150. The control unit 1150 may generate a modulation signal for transmission to the target device 1200 by controlling the power converter 1140. That is, the control unit 1150 may transmit various messages to the target device 1200 through an in-band communication. Further, the control unit 1150 may detect a reflected wave and demodulate a signal received from the target device 1200 through an envelope of the reflected wave.

The control unit 1150 may generate a modulation signal for performing in-band communication by various methods. The control unit 1150 may generate a modulation signal by turning on/off a switching pulse signal. Further, the control unit 1150 may generate a modulation signal by performing a delta-sigma modulation. The control unit 1150 may generate a pulse width modulation signal having a constant envelope.

The control unit 1150 may perform an out-of-band communication using a separate communication channel rather than the resonant frequency. The control unit 1150 may include a communication module such as Zigbee™ and/or Bluetooth™ technology. The control unit 1150 may transmit/receive data to/from the target device 1200 through an out-of-band communication.

The source resonator 1160 may transfer electromagnetic energy to the target resonator 1210. That is, the source resonator 1160 may transfer communication power or charging power to the target device 1200 through magnetic coupling with the target resonator 1210.

The target resonator 1210 may receive the electromagnetic energy from the source resonator 1160. That is, the target resonator 1210 may receive the communication power or charging power from the source device 1100 through magnetic coupling with the source resonator 1160. Further, the target resonator 1210 may receive various messages from the source device 1100 through in-band communication.

The rectifier 1220 may generate a DC voltage by rectifying an AC voltage. That is, the rectifier 1220 may rectify an AC voltage provided to the target resonator 1210 through wireless communication.

Specifically, referring to FIG. 26, the rectifier 1220 according to exemplary embodiment of the inventive concept includes a full-bridge diode rectifier circuit. In this full-bridge diode rectifier circuit, there are two diodes in one path. That is, the current flowing through one path passes through two diodes.

The rectifier 1220 may receive a first output (RF+) and a second output (RF−) of the target resonator 1210, and convert them into a third output (DC+). The first output (RF+) and the second output (RF−) may include differential signals output from the target resonator 1210. The first output (RF+) and the second output (RF−) may include RF differential input signals. The first output (RF+) may include a signal having a positive (+) phase. The second output (RF−) may include a signal having a negative (−) phase.

The third output (DC+) may include a signal output from the rectifier 1220 after the signal is rectified by the rectifier 1220. In an exemplary embodiment, the third output (DC+) includes a DC voltage.

The rectifier 1220 according to the present embodiment includes first to fourth schottky diodes SD1 to SD4, and a capacitor Cr.

The anode electrode of the first schottky diode SD1 is connected to an RF− connector, and the cathode electrode of the first schottky diode SD1 is connected to a DC+ connector. The anode electrode of the second schottky diode SD2 is connected to an RF+ connector, and the cathode electrode of the second schottky diode SD2 is connected to the DC+ connector. The anode electrode of the third schottky diode SD3 is connected to a ground, and the cathode electrode of the third schottky diode SD3 is connected to the RF− connector. The anode electrode of the fourth schottky diode SD4 is connected to ground, and the cathode electrode of the fourth schottky diode SD4 is connected to the RF+ connector.

The capacitor Cr is connected between the DC+ connector and the ground. That is, one terminal of the capacitor Cr is connected to the DC+ connector, and the other terminal of the capacitor Cr is connected to the ground.

The above-described structures of the schottky diode according to exemplary embodiments may be employed as the first to fourth schottky diodes SD1 to SD4. Accordingly, as described above, the schottky diodes SD1 to SD4 may enhance forward characteristics by shortening current paths in vertical and horizontal directions to reduce a resistance and increase a forward current per unit area. In addition, the schottky diodes SD1 to SD4 may enhance forward characteristics without degrading reverse characteristics by adopting a structure for enlarging depletion regions when a reverse bias voltage is applied. Furthermore the schottky diodes SD1 to SD4 may reduce distribution of a forward current by removing a well region at one side of the schottky junction to reduce parameters affecting DC characteristics of the schottky diode.

Referring back to FIG. 25, the DC/DC converter 1230 may adjust the level of the DC voltage output from the rectifier 1220 to correspond to the capacity of the charger 1250. For example, the DC/DC converter 1230 may adjust the level of the DC voltage output from the rectifier 1220 to a voltage ranging from 3 Volts to 10 Volts.

The switch unit 1240 may be turned on/off under the control of the control unit 1260. If the switch unit 1240 is turned off, the control unit 1150 of the source device 1100 may detect a reflected wave. That is, if the switch unit 1240 is turned off, the magnetic coupling between the source resonator 1160 and the target resonator 1210 may be removed.

In this embodiment, the charger 1250 may include a battery. The charger 1250 may charge the battery using the DC voltage output from the DC/DC converter 1230.

The control unit 1260 may establish an in-band communication to transmit/receive data using the resonant frequency. In this case, the control unit 1260 may demodulate a received signal by detecting a signal between the target resonator 1210 and the rectifier 1220, or demodulate a received signal by detecting an output signal of the rectifier 1220. In other words, the control unit 1260 may demodulate the messages received through in-band communication.

Further, the control unit 1260 may modulate a signal to be transmitted to the source device 1100 by adjusting the impedance of the target resonator 1210. Further, the control unit 1260 may demodulate a signal to be transmitted to the source device 1100 by turning on/off the switch unit 1240. For example, the control unit 126 may increase the impedance of the target resonator 1210 such that a reflected wave can be detected in the control unit 1150 of the source device 1100. The control unit 1150 of the source device 1100 may detect a binary number (i.e., “0” or “1”) depending on whether the reflected wave is generated.

The control unit 1260 may perform an out-of-band communication using a communication channel. The control unit 1260 may include a communication module such as Zigbee™ and/or Bluetooth™. The control unit 1260 may exchange data with the source device 1100 through the out-of-band communication.

Although the exemplary embodiments are described with reference to FIGS. 25 and 26 such that the schottky diodes are used in a wireless power transmission system, it should be understood that the schottky diode according to exemplary embodiments may be incorporated into various integrated circuits and systems.

Hereinafter, a method of manufacturing a semiconductor device according to an exemplary embodiment of the inventive concept is described.

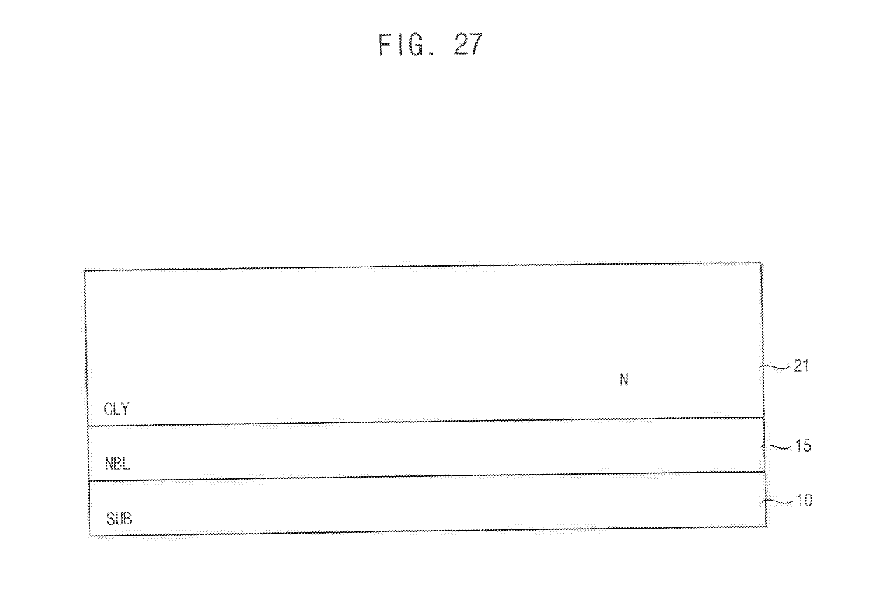

FIGS. 27, 28, 29 and 30 are diagrams illustrating a process of manufacturing a schottky diode according to an exemplary embodiment of the inventive concept.

First, referring to FIG. 27, a buried layer NBL 15 and a conduction layer CLY 21 are sequentially formed on a substrate SUB 10.

The substrate 10 includes a semiconductor material. The substrate 10 may be made of at least one semiconductor material selected from the group comprising, for example, Si, Ge, SiGe, GaP, GaAs, SiC, SiGeC, InAs and InP. A conduction type of the substrate 10 may be, for example, a P-type.

In an exemplary embodiment, the buried layer 15 is formed at a boundary between the substrate 10 and the conduction layer 21. More specifically, a portion of the buried layer 15 is formed on the substrate 10 and the remaining portion of the buried layer 15 is formed on the conduction layer 21. In an exemplary embodiment, after the buried layer 15 is formed in the substrate 10 and the conduction layer 21, an epitaxial layer is formed on the substrate 10, and then a heat treatment is performed. When the heat treatment is in progress, since the buried layer 15 diffuses into the substrate 10 and the epitaxial layer 21, a portion of the buried layer 15 may be formed on the substrate 10 and the remaining portion of the buried layer 15 may be formed on the epitaxial layer 21. For example, a conduction type of the buried layer 15 may be an N-type. For example, a conduction type of the epitaxial layer 21 may be an N-type. In this case, the concentration of N-type impurities contained in the epitaxial layer 21 may be lower than the concentration of N-type impurities contained in the buried layer 15. Further, in an exemplary embodiment of the present inventive concept, the buried layer 15 is omitted.

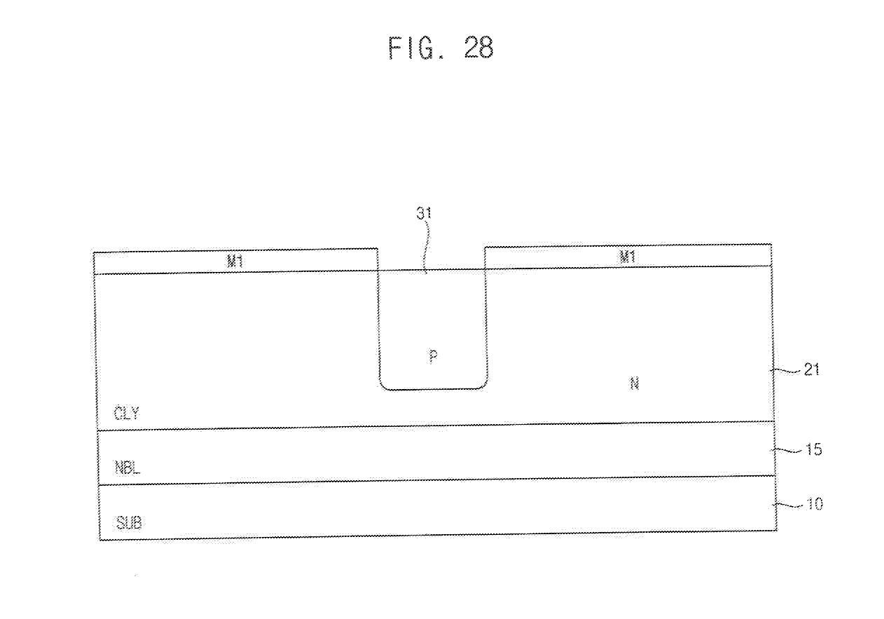

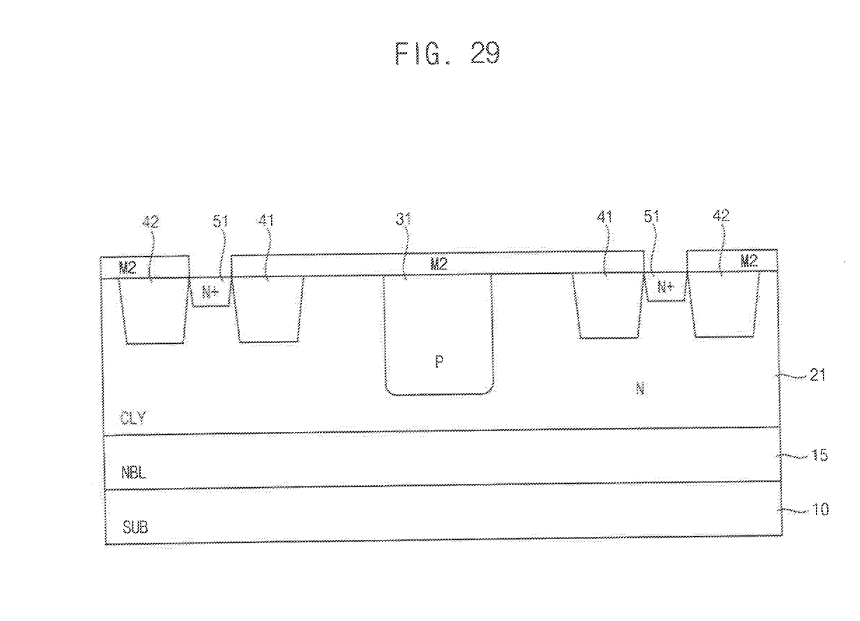

Referring to FIG. 28, a first mask M1 is formed on the epitaxial layer 21. Then, a well region 31 is formed in the epitaxial layer 21 using the first mask Ml. The conduction type of the well region 31 may be the P-type and thus the well region 31 and the conduction layer 21 may form a PN junction. In an embodiment, the impurity concentration of the well region 31 is higher than that of the substrate 10.

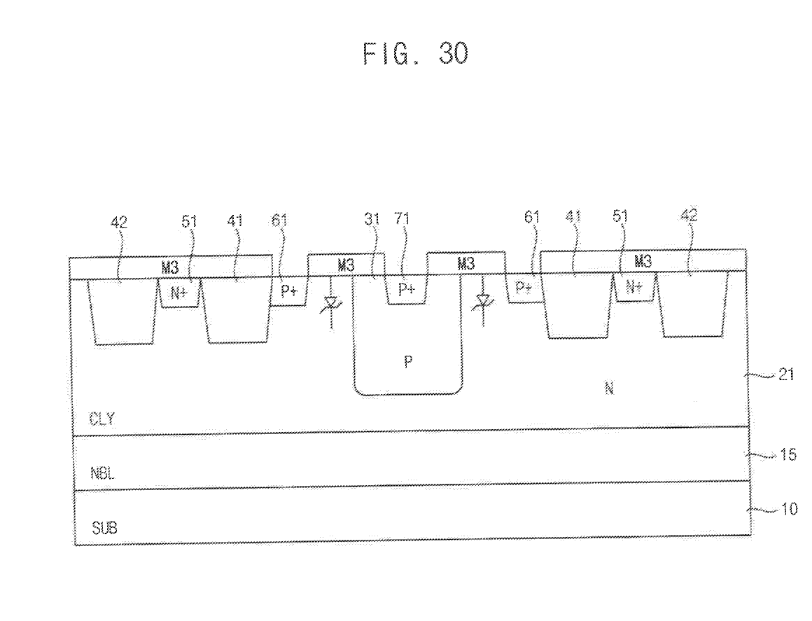

Referring to FIG. 29, isolation regions 41 and 42 are formed in the epitaxial layer 21. Subsequently, a second mask M2 is formed on the epitaxial layer 21. Then, the junction region 51 is formed in the epitaxial layer 21 using the second mask M2. A conduction type of the junction region 51 may be, for example, an N-type. In an embodiment, the impurity concentration of the junction region 51 is higher than that of the conduction layer 21, that is, the epitaxial layer 21.

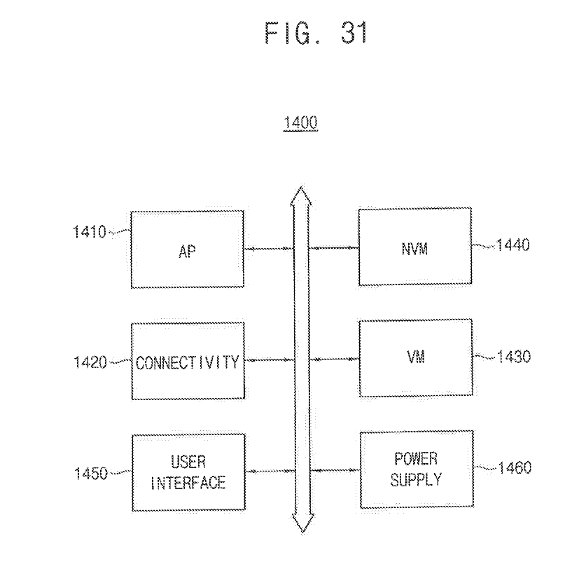

Referring to FIG. 30, a third mask M3 is formed on the epitaxial layer 21. Subsequently, junction regions 61 and 71 are formed in the epitaxial layer 21 using the third mask M3. A conduction type of the junction regions 61 and 71 may be, for example, the P-type. Accordingly the junction region 61 and the conduction layer 21 form an PN junction. In an embodiment, the impurity concentration of the junction regions 61 and 71 is higher than that of the well region 31.

Although FIGS. 29 and 30 illustrate an exemplary embodiment where the N-type junction region 51 is formed first and then the P-type junction regions 61 and 71 are formed next, it should be understood that, in an alternate embodiment, the P-type junction regions 61 and 71 is formed first and the N-type junction region 51 is formed next.

After that, the schottky electrode 81 and the ohmic electrode 91 as described above may be formed to manufacture the schottky diode according to exemplary embodiments.

FIG. 31 is a diagram illustrating a mobile device according to exemplary embodiment of the inventive concept.

Referring to FIG. 31, a mobile device 1400 includes an application processor (AP) 1410, a connectivity unit 1420, a volatile memory device (VM) 1430, a nonvolatile memory device (NVM) 1440, a user interface 1450, and a power supply 1460. In some embodiments, the mobile device 1400 may be an electronic device such as a mobile phone, a smart phone, a personal digital assistant (PDA), a portable multimedia player (PMP), a digital camera, a music player, a portable game console, a navigation system, or another type of electronic device.

The application processor 1410 may execute applications such as a web browser, a game application, a video player, etc. The connectivity unit 1420 may perform wired or wireless communication with an external device. The volatile memory device 1430 may store data processed by the application processor 1410 or may operate as a working memory. The nonvolatile memory device 1440 may store a boot image for booting the mobile device 1400. The user interface 1450 may include at least one input device, such as a keypad, a touch screen, etc., and at least one output device, such as a speaker, a display device, etc. The power supply 1460 may supply a power supply voltage to the mobile device 1400.

The mobile device 1400 may include at least one schottky diode according to the exemplary embodiments as described above. The schottky diode may have a structure of a shortened current path and an enlarged depletion region in case of a reverse bias by forming the schottky region at the upper surface portion of the conduction layer between the well region and the first junction region.

As such, a schottky diode according to at least one exemplary embodiment of the inventive concept may enhance forward characteristics by shortening current paths in vertical and horizontal directions to reduce resistance and increase a forward current per unit area. In addition, the schottky diode according to an exemplary embodiment may enhance forward characteristics without degrading reverse characteristics by adopting a structure for enlarging depletion regions when a reverse bias voltage is applied. Furthermore, the schottky diode according to an exemplary embodiment may reduce distribution of a forward current by removing a well region at one side of the schottky junction to reduce parameters affecting DC characteristics of the schottky diode.

The present inventive concept may be applied to any device or system including a diode. For example, the present inventive concept may be applied to systems such as a mobile phone, a smart phone, a personal digital assistant (PDA), a portable multimedia player (PMP), a digital camera, a camcorder, personal computer (PC), a server computer, a workstation, a laptop computer, a digital TV, a set-top box, a portable game console, a navigation system, etc.

Although a few exemplary embodiments of the inventive concept have been described, those skilled in the art will readily appreciate that many modifications are possible in these exemplary embodiments without materially departing from the scope of the present inventive concept.

1. A schottky diode comprising:
a conduction layer of a first conduction type;
a first well region of a second conduction type disposed in the conduction layer;
a first isolation region disposed in the conduction layer, wherein the first isolation region is spaced apart from the first well region;
a first junction region of the second conduction type disposed in the conduction layer, wherein the first junction region is adjacent to the first isolation region and spaced apart from the first well region;
a second junction region of the first conduction type disposed in the conduction layer, wherein the second junction region is adjacent the first isolation region; and
a schottky electrode covering a schottky junction surface corresponding to an upper surface of the conduction layer between the first well region and the first junction region.

2. The schottky diode of claim 1, further comprising:
a third junction region of the second conduction type disposed in the first well region, the third junction region having a higher impurity concentration than the first well region.

3. The schottky diode of claim 1, wherein the schottky electrode completely covers the first well region and the first junction region.

4. The schottky diode of claim 1, wherein the schottky electrode covers a portion of the first junction region and is spaced apart from the first isolation region.

5. The schottky diode of claim 1, further comprising:
a second well region of the first conduction type disposed under the second junction region, the second well region having an impurity concentration higher than the conduction layer and lower than the second junction region and being deeper than the first isolation region.

6. The schottky diode of claim 1, further comprising:
a second isolation region disposed in the conduction layer, wherein the second isolation region is adjacent the second junction region.

7. The schottky diode of claim 1, wherein the first well region is formed at a center portion of the schottky diode and the first junction region, wherein the first isolation region has a ring shape that surrounds the first well region and the second isolation region has a ring shape that surrounds the first isolation region and the first well region.

8. The schottky diode of claim 7, wherein the schottky junction surface has a ring shape between the first well region and the ring-shaped first junction region.

9. The schottky diode of claim 8, wherein the schottky electrode has a convex polygon shape to cover the first well region, the ring-shaped schottky junction surface and the ring-shaped first junction region.

10. The schottky diode of claim 7, further comprising:
a second isolation region having a ring shape in the conduction layer to surround the ring-shaped second junction region, wherein the ring-shaped second isolation region is adjacent the ring-shaped second junction region.

11. The schottky diode of claim 10, further comprising:
a third junction region of the second conduction type having a ring shape in the conduction layer to surround the ring-shaped second isolation region.

12. The schottky diode of claim 1, wherein the second junction region is disposed at a center portion of the schottky diode and the first isolation region, wherein the first junction region has a ring shape that surrounds the second junction region and the first region has a ring shape that surrounds the first junction region and the second junction region.

13. The schottky diode of claim 12, wherein the schottky junction surface has a ring shape between the ring-shaped first junction region and the ring-shaped first well region.

14. The schottky diode of claim 13, wherein the schottky electrode has a ring shape to cover the ring-shaped first junction region, the ring-shaped schottky junction surface and the ring shaped first well region.

15. The schottky diode of claim 1, further comprising:
an ohmic electrode covering an ohmic junction surface corresponding to an upper surface of the second junction region.

16. The schottky diode of claim 1, wherein, when a reverse voltage is applied to the schottky diode, depletion regions are formed between the conduction layer and the first well region and between the conduction layer and the first junction region.

17. A schottky diode comprising:
a conduction layer of an N-type;
a well region of a P-type disposed in the conduction layer;
a first junction region of the P-type having a ring shape in the conduction layer and surrounding the well region, wherein the ring shaped first junction region is spaced apart from the well region;
an isolation region having a ring shape in the conduction layer and surrounding the ring-shaped first junction region, wherein the ring-shaped isolation region is adjacent the ring-shaped first junction region;
a second junction region of the N-type having a ring shape in the conduction layer and surrounding the isolation region, wherein the ring-shaped second junction region is adjacent the ring-shaped isolation region; and
a schottky electrode covering a schottky junction surface corresponding to an upper surface of the conduction layer between the first well region and the ring-shaped first junction region.

18. An integrated circuit comprising:
a plurality of schottky diodes arranged in a two-dimensional plane, each of the schottky diodes comprising:
a conduction layer of a first conduction type;
a well region of a second conduction type disposed in the conduction layer;
an isolation region disposed in the conduction layer, wherein the isolation region is spaced apart from the well region;
a first junction region of the second conduction type disposed in the conduction layer, wherein the first junction region is adjacent the isolation region and spaced apart from the well region;
a second junction region of the first conduction type disposed in the conduction layer, wherein the second junction region is adjacent the isolation region;
a schottky electrode covering a schottky junction surface corresponding to an upper surface of the conduction layer between the first well region and the first junction region; and
an ohmic electrode covering an ohmic junction surface corresponding to an upper surface of the second junction region.

19. The integrated circuit of claim 18, wherein the schottky electrodes of the plurality of schottky diodes are arranged in a form of a matrix of at least one row and at least one column, and the ohmic electrodes of the plurality of the schottky diodes are formed in a shape of a mesh to surround the schottky electrodes.

20. The integrated circuit of claim 18, wherein the ohmic electrodes of the plurality of schottky diodes are arranged in a form of a matrix of at least one row and at least one column, and the schottky electrodes of the plurality of the schottky diodes are formed in a shape of a mesh to surround the ohmic electrodes.

21-23. (canceled)
